(19) United States
(12) Patent Application Publication
(10) Pub. No.: US 2024/0291071 A1
(43) Pub. Date: Aug. 29, 2024

(54) TEMPERATURE-REGULATING DEVICE

(71) Applicant: Valeo Systemes Thermiques, Le Mesnil-Saint-Denis (FR)

(72) Inventors: Julien Tissot, Le Mesnil-Saint-Denis (FR); Jeremy Blandin, Le Mesnil-Saint-Denis (FR); Kamel Azzouz, Le Mesnil-Saint-Denis (FR)

(73) Assignee: Valeo Systemes Thermiques, Le Mesnil-Saint-Denis (FR)

(21) Appl. No.: 18/572,425

(22) PCT Filed: Jun. 14, 2022
(86) PCT No.: PCT/EP2022/066219

§ 371 Date: Dec. 20, 2023

(30) Foreign Application Priority Data
Jun. 21, 2021 (FR) 2106559

(51) Int. Cl. H01M 10/6568; H01M 10/613; H01M 10/625

(52) U.S. Cl. CPC H01M 10/6568; H01M 10/613; H01M 10/625; H01M 2220/20

(57) ABSTRACT

A temperature-regulating device for electronic or electrical components which can release heat when in operation is disclosed. The temperature-regulating device includes a housing which is configured to accommodate the electrical or electronic components. The temperature-regulating device also includes means for regulating the temperature of the components with a dielectric fluid which is able to immerse the components at least partly. The temperature-regulating means include firstly a heat exchanger through which the dielectric fluid can pass and a heat transfer fluid. The heat exchanger includes at least one dielectric fluid input and one dielectric fluid output. The temperature regulating means further includes a system for distribution of the dielectric fluid which is positioned at the dielectric fluid output of the heat exchanger and at least two dielectric fluid spraying orifices.

The present invention comes within the field of temperature-regulating devices for electrical or electronic components, and more particularly it relates to a temperature-regulating device for electrical or electronic components which can heat up when they are operating.

The electrical or electronic components which the present invention may concern can also consist of computer servers as well as electrical energy storage systems, in particular batteries for motor vehicles.

In the field of motor vehicles, temperature-regulating devices make it possible to modify a temperature of an electric battery, either during starting of the vehicle in cold weather, by increasing its temperature for example, or during travel, or during an operation of recharging of the battery, by decreasing the temperature of this electric battery, which tends to heat up when it is being used.

In general, temperature-regulating devices of this type for electric batteries use heat exchangers. The different battery cells of an electrical storage system can in particular be cooled by means of a cold plate, in the interior of which a cooling fluid circulates, the plate being in contact with the battery cells to be cooled. It has been found that heat exchangers of this type can lead to irregular cooling of the electric batteries of a single electrical storage system, thus giving rise to a decrease in the global performance of the electrical storage system. These temperature-regulating devices also have a high level of thermal resistance, because of the thicknesses of material present between the cooling fluid and the battery cells.

For the purpose of providing a response to these different problems, devices are known for cooling electric battery elements of electric or hybrid motor vehicles comprising a hermetically sealed housing in which the battery elements of the electrical energy storage system are partly immersed in a dielectric fluid. This therefore assures an exchange of heat between the battery elements and the dielectric fluid, with a dielectric fluid tank being situated on the exterior of the housing, and connected to said housing by means of a pump, in order to permit the circulation of the dielectric fluid and topping up of this dielectric fluid in the interior of the housing. By this means, the dielectric fluid, which is put into motion and cooled before its return to the housing, can also circulate in the interior of the housing around electrical storage cells. However, it should be noted that, when the cooled dielectric fluid is put into motion by the pump, the storage cells which are positioned furthest from the intake of dielectric fluid into the housing are less well cooled by exchange of calories with the dielectric fluid than the storage cells which are situated closest to the dielectric fluid intake, such that the cooling of the electrical or electronic components is not carried out homogeneously.

The present invention comes within this context, and its main objective is a temperature-regulating device for a plurality of electrical and/or electronic components which can release heat when they are operating, the temperature-regulating device comprising a housing which is configured to accommodate the electrical and/or electronic components, and means for regulating the temperature of the electrical and/or electronic components by means of a dielectric fluid which can immerse the electrical and/or electronic components at least partly, characterized in that the temperature-regulating means comprise firstly a heat exchanger through which the dielectric fluid can pass, and a heat-transfer fluid, with the heat exchanger comprising at least one dielectric fluid input and one dielectric fluid output, the temperature-regulating means also comprising a system for distribution of the dielectric fluid which is positioned at the dielectric fluid output of the heat exchanger, and comprises at least two dielectric fluid spraying orifices, the distribution system participating in delimiting at least partly a duct which extends in a main direction of extension in the prolongation of the dielectric fluid output of the heat exchanger, the duct being configured such as to have a variable cross-section of passage for the dielectric fluid.

The temperature-regulating device is designed to reduce the temperature of a plurality of electrical and/or electronic components thanks to the circulation of the cooled dielectric fluid between the electrical and/or electronic components. The dielectric fluid is also cooled by exchange of calories with the heat-transfer fluid at the heat exchanger. It is understood from this that the dielectric fluid is cooled in the heat exchanger by exchange of calories with the heat-transfer fluid, then is directed to the electrical and/or electronic components, in order to cool them in their turn.

In particular, the device is advantageous in the case when the electrical and/or electronic components accommodated in the housing are positioned in succession in a direction of extension of the housing, parallel to the main direction of extension of the duct, with the dielectric fluid then being able to be directed directly facing, or in the vicinity of, electrical and/or electronic components positioned at the end of this succession of components which is opposite the heat exchanger.

The dielectric fluid is directed from the heat exchanger through the distribution system, and more specifically through the duct which is delimited by the distribution system. After having been cooled by exchanging calories with the heat-transfer fluid, the dielectric fluid circulates in the duct from the dielectric fluid output of the heat exchanger, as far as the spraying orifices of the distribution system. Thanks to the distribution system, the cooled dielectric fluid is distributed homogeneously at the level of the different electrical and/or electronic components. The distribution system thus makes it possible to cool a maximum of electrical and/or electronic components, and in particular to prevent the electrical and/or electronic components which are furthest from the dielectric fluid output of the heat exchanger from being less well cooled than others.

The variation of the cross-section of passage of the duct from the axial end of the duct facing a dielectric fluid output of the heat exchanger as far as the other axial end of the duct is configured such that the objective is to vary the speed of flow of the dielectric fluid circulating the duct going away from the dielectric fluid output of the heat exchanger.

The objective is also to control the losses of load at each variation of cross-section of passage from one portion of duct to another, with these load losses making it possible to force the dielectric fluid to be distributed homogeneously along the entire dimension of extension of the duct.

According to an optional characteristic of the invention, the orifices for spraying of the dielectric fluid are distributed along the duct, in the main direction of extension of this duct. The distribution of the spraying orifices along the duct optimizes regular spraying of the cooled dielectric fluid along the entire length of the duct, such as to permit homogeneous cooling of the electrical and/or electronic components irrespective of their position in the temperature-regulating device.

According to another optional characteristic of the invention, the spraying orifices are distributed in pairs, with the orifices for spraying of the dielectric fluid of each pair being positioned opposite one another relative to a direction perpendicular to the main direction of extension of the duct. It is understood that the spraying orifices are thus configured to spray fluid in opposite directions, which is particularly advantageous when the duct extends between two rows of electrical or electronic components, in order to direct the dielectric fluid towards each of these rows.

According to another optional characteristic of the invention, the duct has a circular cross-section of passage, with the spraying orifices of a single pair being positioned diametrically opposite one another.

According to another optional characteristic of the invention, the cross-section of passage of the duct decreases going away from the dielectric fluid output of the heat exchanger. In other words, a dimension of the cross-section of passage of the duct measured at the dielectric fluid output of the heat exchanger is larger than a dimension of the cross-section of passage of the duct measured at an end of the duct which is axially opposite the dielectric fluid output of the heat exchanger. “Axially” means that reference is being made to the main direction of extension of the duct.

According to another optional characteristic of the invention, the cross-section of passage of the duct decreases continuously going away from the dielectric fluid output of the heat exchanger. In other words, the distribution system participates in defining a duct with a frusto-conical form, the tip of the cone of which is axially opposite the dielectric fluid output of the heat exchanger.

According to another optional characteristic of the invention, the cross-section of passage of the duct decreases in successive steps going away from the dielectric fluid output of the heat exchanger, forming a plurality of successive portions with different cross-sections of passage. Each step of the duct can be defined by a part of the duct at the level of which the cross-section of passage of the duct is constant. It is understood here that the cross-section of passage of each of the steps of the duct has a cross-section of passage with a dimension smaller than the cross-section of passage of the preceding step, in the direction of circulation of the dielectric fluid, from the dielectric fluid output of the heat exchanger as far as the free end of the distribution system.

According to another optional characteristic of the invention, in a context where the duct has a plurality of successive portions with different cross-sections of passage, a first portion of the duct is connected to the dielectric fluid output of the heat exchanger, with the first portion of the duct having a cross-section of passage larger than the corresponding cross-section of passage of the other portion(s) of the duct.

According to another optional characteristic of the invention, the successive portions of the duct have cross-sections of passage with values which decrease in the main direction of extension of the duct, from the dielectric fluid output of the heat exchanger as far as a free end of the distribution system.

According to another optional characteristic of the invention, the distribution system comprises at least one dielectric fluid spraying orifice which is positioned on a portion of the duct, and at least one second dielectric fluid spraying orifice which is positioned on another portion.

According to another optional characteristic of the invention, the distribution system comprises a plurality of dielectric fluid spraying orifices, with the number of spraying orifices being at least equal to the number of portions with different cross-sections which the duct comprises.

According to another optional characteristic of the invention, the distribution system comprises at least one dielectric fluid spraying orifice positioned on each portion of the duct.

According to another optional characteristic of the invention, the distribution system comprises at least two dielectric fluid spraying orifices positioned on each portion of the duct on both sides of the main direction of extension of the duct.

According to another optional characteristic of the invention, the duct is formed by a plurality of coaxial tubular elements with different transverse cross-sections and different lengths. Each tubular element starts at the dielectric fluid output of the heat exchanger. It is understood that the tubular elements are imbricated in one another, such that at least one tubular element extends around another tubular element, and the different lengths, measured along their common axis from the heat exchanger, make it possible to create for each tubular element a free portion which is not covered by other tubular elements, via which the dielectric fluid can exit in the direction of the electrical and/or electronic components.

According to another optional characteristic of the invention, each portion of the duct is formed by a free portion of one of the tubular elements which is not covered by another tubular element.

According to another optional characteristic of the invention, at least one spraying orifice is positioned at the free portion of each of the tubular elements.

According to another optional characteristic of the invention, the distribution system comprises at least one shell which participates in delimiting the duct at least partly, with the housing comprising a plurality of walls which participate in delimiting the receptacle for accommodation of the electrical and/or electronic components, at least one of the walls of the housing and said shell being able to cooperate in order to delimit the duct. In this case, the duct is formed both by the shell of the distribution system and at least one wall of the housing participating in accommodating the electrical and/or electronic components.

The subject of the invention is also an electronic system comprising electrical and/or electronic components, and a temperature-regulating device as previously described, the electrical and/or electronic components being distributed in at least two rows, the rows extending parallel to a main direction of extension of the duct, the distribution system extending at least partly between two rows of electrical and/or electronic components.

According to another optional characteristic of the invention, the dielectric fluid spraying orifices are positioned on the duct such as to be facing one of the electrical and/or electronic components. It is understood that the dielectric fluid is sprayed directly onto the electrical and/or electronic components, and thus optimizes the electrical and/or electronic components.

According to another optional characteristic of the invention, in particular in the case previously described where the distribution system comprises at least one first dielectric fluid spraying orifice which is positioned on a portion of the duct, and at least one second dielectric fluid spraying orifice which is positioned on another portion, the first spraying orifice is positioned in line with one of the electrical and/or electronic components, the second spraying orifice being positioned in line with another one of the electrical and/or electronic components.

According to another optional characteristic of the invention, each spraying orifice is positioned in line with one of the electrical and/or electronic components.

According to another optional characteristic of the invention, each electrical and/or electronic component is positioned in line with one of the spraying orifices.

Other characteristics, details and advantages of the invention will become more clearly apparent, on the one hand on reading the following description, and on the other hand from a number of examples of embodiments given by way of non-limiting indication, with reference to the appended schematic drawings, in which:

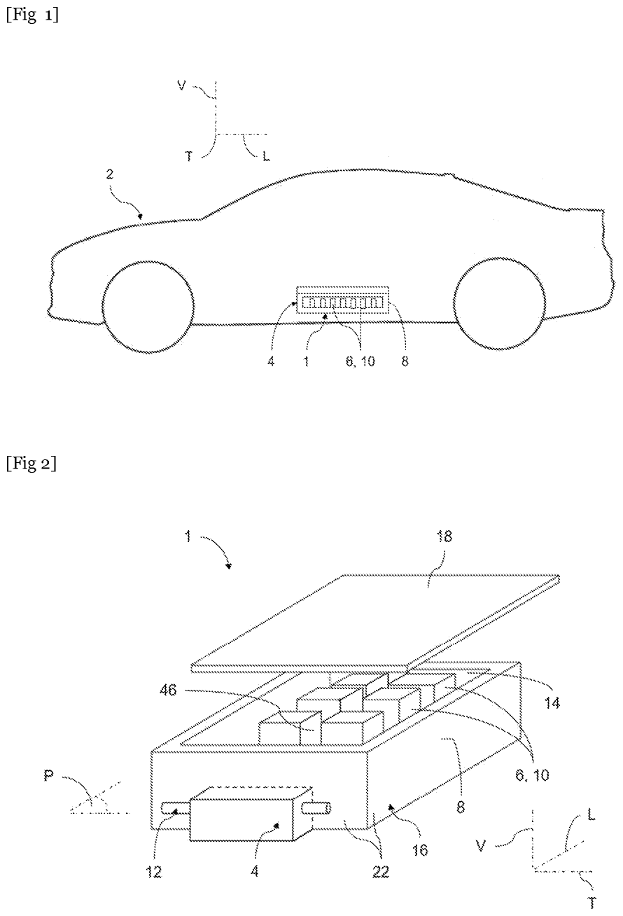

FIG. 1 is a general view of an electrical storage system accommodated within a motor vehicle, comprising a temperature-regulating device and electrical and/or electronic components;

FIG. 2 is a general view in perspective of a housing of the temperature-regulating device of FIG. 1, comprising the electrical and/or electronic components;

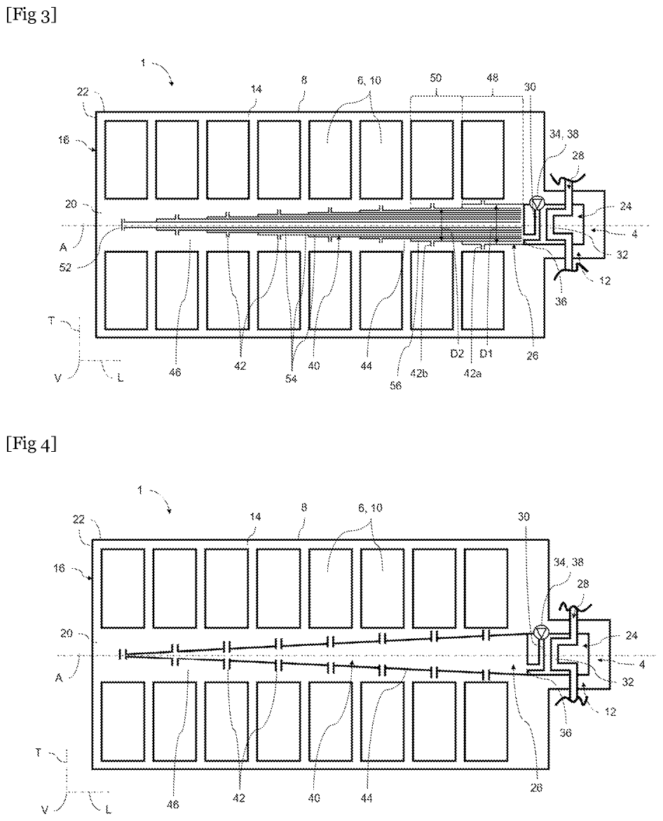

FIG. 3 is a view along a longitudinal cross-section of the temperature-regulating device of FIG. 2, in which there is accommodated a system for distribution of a dielectric fluid according to a first embodiment, and a heat exchanger through which the dielectric fluid passes, and a heat-transfer fluid;

FIG. 4 is a view along a longitudinal cross-section of the temperature-regulating device of FIG. 2, in which there is accommodated a system for distribution of a dielectric fluid according to a second embodiment, and a heat exchanger through which the dielectric fluid passes, and a heat transfer fluid.

The characteristics, variants and different embodiments of the invention can be combined with one another, in various combinations, provided that they are not mutually incompatible or mutually exclusive. It will be possible, in particular, to conceive of variants of the invention that comprise only a selection of the characteristics described below, in isolation from the other characteristics described, if this selection of characteristics is sufficient to confer a technical advantage and/or to distinguish the invention from the prior art.

In the figures, elements that are common to multiple figures retain the same reference.

In the following detailed description, the terms “longitudinal”, “transverse” and “vertical” refer to the orientation of a distribution system according to the invention. A longitudinal direction corresponds to a main direction of extension of the duct of the distribution system, this longitudinal direction being parallel to a longitudinal axis L, of an L, V, T illustrated in the figures. A transverse direction corresponds to a direction in which the spraying orifice extends mainly, with this transverse direction being parallel to a transverse axis T of the reference system L, V, T, and this transverse axis T being perpendicular to the longitudinal axis L. Finally, a vertical direction corresponds to a direction parallel to the vertical axis V of the reference system L, V, T, this vertical axis V being perpendicular to the longitudinal axis L and the transverse axis T.

In addition the terms “upstream” and “downstream” used hereinafter in the description refer to the direction of circulation of a dielectric fluid through the temperature-regulating device.

In addition, in the following detailed description, the temperature-regulating device according to the invention will be described in relation with an electronic system in the form of a motor vehicle electrical energy storage system, but it should be understood that an application of this type is non-limiting, and that in particular it could be applied within the context of the invention to electrical or electronic components which equip other electronic systems, and for example computer servers.

In FIGS. 1 and 2, an electrical storage system 1, which in particular can equip a motor vehicle 2 with electrical or hybrid motorization, is illustrated. An electrical storage system 1 of this type is designed in particular to supply electrical energy to the motor vehicle 2 for the purpose of its travel.

The electrical storage system 1 comprises a temperature-regulating device 4 which is configured to cool or increase the temperature of each electrical or electronic component 6 forming part of the electrical storage system 1, these components being liable in particular to heat up when they are operating or being charged.

More particularly, this temperature-regulating device 4 comprises at least one housing 8 which is configured to receive a plurality of said electrical and/or electronic components 6, which in this case are in the form of battery elements 10, and it also comprises temperature-regulating means 12 which can regulate the temperature of the electrical or electronic components 6 in the interior of the housing 8. It should be noted that other configurations of the electrical storage system 1 could be implemented according to the invention, provided that this system comprises a temperature-regulating device 4 according to the invention.

The housing 8 comprises a plurality of walls which define in the interior of this housing 8 a receptacle 14, shown more particularly in FIG. 2, which is configured to receive at least the electrical and/or electronic components 6 and the temperature-regulating means 12. The walls which define the housing 8 form in particular a base 16 and a cover 18.

The base 16 comprises a base wall 20 and a plurality of lateral walls 22. More specifically, the base wall 20 extends on a plane parallel to the longitudinal L and transverse T directions globally in the form of a quadrilateral, which is advantageously rectangular, with the lateral walls 22 for their part each extending from a side of the base wall 20, while being inscribed on a plane parallel to the longitudinal L and vertical V directions. In other words, the lateral walls 22 extend from the base wall 20 perpendicularly thereto.

The cover 18 has a form substantially identical to that of the base wall 20, and therefore in this case in the form of a quadrilateral which is advantageously rectangular, and is designed to cover the base 16 of the housing 8 and close the opening between the lateral walls 22 by means of which the electrical and/or electronic components 6 are placed in the receptacle 14. It is understood in particular that the cover 18 is positioned on top of the base 16, in contact with the free edges of the lateral walls 22, in particular when the electrical storage system 1 is fitted on the motor vehicle 2.

In addition, the base 16 and the cover 18 are secured to one another such as to make the receptacle 14 of the housing 8 hermetically sealed against the external environment of the housing 8. “Hermetically sealed” means that the base 16 and the cover 18 are rendered integral with one another, such that no exchange of fluid can take place between the interior of the receptacle 14 of the housing 8 and the external environment of the housing 8 at the level of the interaction between the base and the cover.

As illustrated in FIGS. 3 and 4, the electrical and/or electronic components 6 are positioned in the receptacle 14 of the housing 8 in the form of at least two rows, i.e. the electrical and/or electronic components 6 form two assemblies which are aligned in a direction parallel to the longitudinal direction L. A first part of the electrical and/electronic components 6 forms a first assembly positioned in the form of a first row of electrical and/or electronic components 6 which are aligned in a first direction parallel to the longitudinal direction L, and a second part of the electrical and/or electronic components 6 forms a second assembly which is positioned in the form of a second row of electrical and/or electronic components 6 aligned in a second direction parallel to the longitudinal direction L and the first direction. In this configuration, the two rows of electrical and/or electronic components 6 contribute to delimiting in the receptacle 14 a path 46 for circulation of fluid between the rows, this path also being shown in FIG. 2.

As shown more particularly in FIGS. 3 and 4, which represent the electrical storage system 1 seen on a longitudinal and transverse cross-sectional plane P, the temperature-regulating means 12 comprise in particular a heat exchanger 24, which can cool a dielectric fluid destined to be sprayed on the electrical and/or electronic components, and a system 26 for distribution of the dielectric fluid in the receptacle 14 of the housing 8.

The dielectric fluid participates in the temperature regulation of the electrical and/electronic components 6 by exchanging calories with said electrical and/or electronic components 6. For this purpose, the dielectric fluid is contained in the receptacle 14 of the housing 8, and immerses the electrical and/or electronic components 6 at least partly, thus permitting the exchange of calories over all of the outer surface of the immersed electrical and/or electronic components 6. Advantageously, all of the electrical and/or electronic components 6 are totally immersed in the dielectric fluid, thus optimizing their temperature regulation by the dielectric fluid.

According to the invention, the heat exchanger 24 permits the exchange of calories between the dielectric fluid and a heat-transfer fluid circulating through a heat-transfer fluid circuit 28. For this purpose, and as illustrated in FIGS. 3 and 4, the heat exchanger 24 comprises a first passage 30 through which the dielectric fluid can circulate, and a second passage 32 through which the heat-transfer fluid can circulate.

The first passage 30 has a dielectric fluid input 34, which is fluidically connected to the receptacle 14 in which the dielectric fluid is contained, and a dielectric fluid output 36, which is fluidically connected to the system 26 for distribution of dielectric fluid. The second passage 32 for its part constitutes a heat-transfer fluid circuit, which moreover is outside the electrical storage system 1. The exchange of calories between the dielectric fluid and the heat-transfer fluid takes place when said dielectric and heat-transfer fluids circulate respectively through their passage 30, 32. For example, the dielectric fluid which circulates in the first passage 30 can yield calories to the heat-transfer fluid circulating in the second passage 32, with the temperature of the dielectric fluid thus being decreased by this loss of calories, or, the dielectric fluid circulating in the first passage 30 can capture calories yielded by the heat transfer fluid circulating in the second passage 32, with the temperature of the dielectric fluid thus being increased by this addition of calories.

It is understood from the foregoing that the temperature of the dielectric fluid is thermally regulated at the heat exchanger 24 by the heat-transfer fluid, thanks to an exchange of calories between the dielectric fluid circulating in the first passage 30, and the heat-transfer fluid circulating in the second passage 32.

According to the invention, the temperature-regulating means 12 comprise a pumping unit 38, which forces the circulation of the dielectric fluid through the heat exchanger 24. More specifically, the pumping unit 38 forces the circulation of the dielectric fluid through the first passage 30 of the heat exchanger 24.

Advantageously, the pumping unit 38 is configured to force the circulation of the dielectric fluid firstly through the heat exchanger 24, and secondly through the distribution system 26, and also through the receptacle 14. Thanks to the pumping unit 38, which aspirates some of the dielectric fluid present in the receptacle, and generates movement of the dielectric fluid in which the electrical and/or electronic components 6 are immersed, the dielectric fluid is thermally regulated by circulating through the heat exchanger 24, before circulating within the distribution system 26 present in the receptacle 14 and being directed at the output of this distribution system 26 directly to the electrical and/or electronic components 6, which are thus supplied with dielectric fluid which is cooled, and better able to assure their thermal regulation.

According to the example illustrated in FIGS. 3 and 4, the pumping unit 38 is preferably positioned at the dielectric fluid input 34 of the heat exchanger 24. In this arrangement, the pumping unit 38 aspirates some of the dielectric fluid contained in the receptacle 14 and then propels it through the first passage 30 of the heat exchanger 24.

As previously stated, the propulsion of the dielectric fluid in the first passage 30 by the pumping unit 38 is sufficiently powerful to put the dielectric fluid in motion through the assembly of the components of the temperature-regulating device 4.

According to an alternative, not represented in the figures, the pumping unit 38 can for example be positioned at the dielectric fluid output 36 or at the distribution system 26. It is understood from this that, more generally, the pumping unit 38 can be positioned equally well at the heat exchanger 24 of the distribution system 26, or in the receptacle 14, without departing from the context of the invention, provided that the objective set out by the invention is fulfilled, which, as a reminder, is to force the circulation of the dielectric fluid through the heat exchanger 24, the distribution system 26 and/or the receptacle 14.

In the example illustrated, the heat exchanger is accommodated in the housing, but it should be noted that, without departing from the context of the invention, the heat exchanger could be positioned outside the housing, provided that the first passage 30 associated with the dielectric fluid and the dielectric fluid output 36 are connected fluidically to the distribution system, which, for its part, according to the invention extends within the housing.

More particularly, the heat exchanger 24 can in particular, as shown in FIGS. 2 to 4, be positioned in the interior of the housing facing a lateral wall, and in particular in the interior of a recess 25 formed in one of the lateral walls, in order not to reduce the space available for the electrical and/or electronic components 6. A compartmentalization wall can be provided in order to close this recess, and allow the heat exchanger to be dry, i.e. not in contact with the dielectric fluid which is present in the receptacle, or, the recess can be filled with dielectric fluid with the heat exchanger immersed, on the understanding that this heat exchanger is sealed against any intake of dielectric fluid other than at the dielectric fluid input 34.

According to the invention, the distribution system 26 is installed at the dielectric fluid output 36 of the heat exchanger 24. In other words, the distribution system 26 is positioned downstream from the heat exchanger 24, i.e. the dielectric fluid circulates through the heat exchanger 24, and more specifically through the first passage 30, before circulating in the distribution system 26.

In addition, the distribution system 26 extends mainly between two rows of electrical and/or electronic components 6. More particularly, the distribution system 26 extends in the fluid circulation path 46 delimited at least partly by the two rows of electrical and/or electronic components 6.

The distribution system 26 participates in defining at least partly a duct 40 and at least two dielectric fluid spraying orifices 42, which make it possible to direct the dielectric fluid circulating in the duct 40 to the interior of the receptacle 14, and in the direction of the electrical and/or electronic components 6. In this configuration, the dielectric fluid output 36 of the heat exchanger 24 opens into the duct 40 of the distribution system 26, with the dielectric fluid circulating through the duct 40 from the dielectric fluid output 36 as far as one of the spraying orifices 42.

By way of example, the heat exchanger can consist of a tube exchanger within which the heat-transfer fluid circulates, with the dielectric fluid passing through the exchanger from a first face to a second face, passing between the tubes, and, in this case, the distribution system starts at the second face.

It is understood from the foregoing that the dielectric fluid is thermally regulated at the heat exchanger 24 before circulating downstream therefrom via the distribution system 26.

The duct 40 of the distribution system 26 extends in a main direction of extension A in the prolongation of the dielectric fluid output 36 of the heat exchanger 24, with the main direction of extension A of the duct 40 being substantially parallel to the longitudinal direction L.

The duct 40 is mainly delimited by at least one inner face of a tubular wall 44 of the distribution system 26. The spraying orifices 42 pass through the tubular wall 44, with the dielectric fluid circulating in the duct 40 being sprayed into the receptacle 14, passing through the tubular wall 44 at the spraying orifices 42.

The spraying orifices 42 are globally in the form of channels extending radially in the tubular wall 44 which delimits the duct 40, with each channel being open firstly onto the duct 40, and secondly onto the receptacle 14, and being able to have a cross-section of passage with a form which is circular, rectangular, or another form.

According to the invention, the orifices 42 for spraying of the dielectric fluid are distributed along the duct 40 in the main direction of extension A of this duct 40, such that the dielectric fluid circulating in the duct 40 can be sprayed in the receptacle 14 along the entire duct 40.

Advantageously, the spraying orifices 42 are distributed along the duct 40 regularly. In other words, the same distance separates each of the spraying orifices 42 from the adjacent spraying orifices 42, with this distance being measured in a direction parallel to the main direction of extension A. The regular position along the duct 40 of the spraying orifices 42 permits homogeneous spraying of the dielectric fluid along the length of the duct 40, thus permitting homogeneous cooling of the electrical and/or electronic components 6 distributed along the distribution system 26.

As illustrated in FIGS. 3 and 4, the spraying orifices 42 are distributed in pairs, with the spraying orifices 42 of the dielectric fluid of each pair being positioned opposite one another, in order to spray dielectric fluid in opposite directions. In the example illustrated, the spraying orifices 42 of a single pair are aligned in a direction substantially parallel to the transverse direction T. In the case illustrated where the duct 40 has a circular cross-section of passage, the spraying orifices 42 of a single pair are diametrically opposite one another.

Preferably, the dielectric fluid spraying orifices 42 are positioned on the duct 40 such as to be facing one of the electrical and/or electronic components 6. This arrangement of the spraying orifices 42 optimizes the thermal regulation of the electrical and/or electronic components 6 by permitting spraying of dielectric fluid which is thermally regulated at the heat exchanger 24, directly onto one of the electrical and/or electronic components 6.

As illustrated in FIGS. 3 and 4, each spraying orifice 42 of the distribution system 26 is positioned on the duct 40, such as to be in line with one of the electrical and/or electronic components 6. In this configuration, a maximum of electrical and/or electronic components 6 is thermally regulated by the dielectric fluid sprayed by the distribution system 26.

Also, in the examples illustrated in FIGS. 3 and 4, each electrical and/or electronic component 6 is positioned in line with one of the spraying orifices 42 of the distribution system 26. It is understood that in this alternative, each electrical and/or electronic component 6 is designed to receive directly dielectric fluid sprayed by the distribution system 26, thus optimizing the regulation of the set of electrical and/or electronic components 6.

According to the invention, the duct 40 is configured such as to have a variable cross-section of passage of the dielectric fluid. The cross-section of passage corresponds to a section of the duct 40 which is delimited by the inner face of the tubular wall 44 seen on a cross-sectional plane perpendicular to the main direction of extension A. The cross-section of passage of the dielectric fluid of the duct 40 is variable, in that the cross-section of passage measured at an axial end of the duct 40 is different, i.e. larger or smaller, than a cross-section of passage of the dielectric fluid of the duct 40 measured at another axial end of said duct 40. It is thus understood that the duct 40 has a plurality of cross-sections of passage of dielectric fluid with different dimensions.

Advantageously, and as illustrated in FIGS. 3 and 4, the cross-section of passage of the duct 40 decreases going away from the dielectric fluid output 36 of the heat exchanger 24. In this configuration, the cross-section of passage of the duct 40 measured at an axial end of the duct 40 facing the dielectric fluid output 36 is larger than a cross-section of passage of the duct 40 measured at the other axial end of the duct 40, i.e. the free end of the duct opposite the heat exchanger 24.

The progressive decrease in the cross-section of passage of the duct 40 from the axial end of the duct 40 facing the dielectric fluid output 36 as far as the other axial end of the duct 40 makes it possible to increase the speed of flow of the dielectric fluid circulating in the duct 40 going away from the dielectric fluid output 36 of the heat exchanger 24.

This decrease, going away from the heat exchanger, of the cross-section of passage of the dielectric fluid, thus has the effect of generating load losses at each reduction of the cross-section of passage from one portion of duct to another, with these load losses making it possible to force the dielectric fluid to be distributed homogeneously along the entire dimension of extension of the duct.

According to different alternative embodiments of the distribution system 26, the tubular wall delimiting the duct can be made in a single piece, and added on facing one of the walls of the housing 8, or this tubular wall can be formed by joining a shell and a complementary form integral with one of the walls of the housing 8 participating in delimiting the receptacle 14. In these two alternatives, the wall of the housing referred to can in particular be the base wall 20 of the housing, on the understanding that the duct could be positioned in the vicinity of one of the lateral walls 22 or the cover 18 of the housing 8, without departing from the context of the invention.

A description will now be provided in greater detail of a first embodiment of the invention with reference to FIG. 3, before describing a second embodiment of the invention with reference to FIG. 4, thus illustrating two different cases for production of the variable cross-section of passage of the duct.

As illustrated in FIG. 3, the cross-section of passage of the duct 40 decreases in successive steps going away from the dielectric fluid output of the heat exchanger 24, forming a plurality of successive portions with different cross-sections of passage. Thus, each portion of the duct 40 can be defined by a part of the duct at the level of which the cross-section of passage of the duct 40 is constant.

A first portion 48 and a second portion 50 of the duct 40 are defined, with the first portion 48 having a cross-section of passage of the dielectric fluid which is larger than that of the second portion 50. It is understood that a first dimension D1 corresponding to the inner diameter of the duct 40 measured at the first portion 48 is larger than a second dimension D2 corresponding to the inner diameter of the duct 40 measured at the second portion 50. As previously stated, the variable cross-section of passage of the duct is such that the cross-section of passage decreases going away from the heat exchanger, and, in this context, as illustrated in FIG. 3, the first portion 48 of the duct 40 is positioned closer to the heat exchanger 24 than the second portion 50, with the first portion 48 of the duct 40 being connected directly to the dielectric fluid output 36 of the heat exchanger 24.

More particularly, the duct 40 comprises a plurality of portions with different cross-sections, with the first portion 48 having the largest cross-section of passage compared with the other portions of the duct 40. The successive portions of the duct 40 have cross-sections of passage with values which decrease in the main direction of extension A of the duct 40, from the dielectric fluid output 36 of the heat exchanger 24 as far as a free end 52 of the distribution system 26. It is understood from the foregoing that the cross-section of passage of each of the portions of the duct 40 has a cross-section of passage with a dimension smaller than the cross-section of passage of the preceding portion, in the direction of circulation of the dielectric fluid in the distribution system 26. In other words, the second portion 50 of the duct 40 has a cross-section of passage smaller than that of the first portion 48 of the duct 40, the cross-section of passage of the second portion 50 of the duct being however larger than the cross-sections of passage of the portions of the duct 40 which are positioned between the second portion 50 and the free end 52 of the distribution system 26.

In this first embodiment, the distribution system 26 comprises at least one first dielectric fluid spraying orifice 42a, which is positioned on the first portion 48 of the duct 40, and at least one second orifice 42b for spraying of dielectric fluid, which is positioned on the second portion 50 of the duct 40. The dielectric fluid which circulates in the first portion 48 of the duct 40 can be sprayed into the receptacle 14 at the first spraying orifice 42a, with the dielectric fluid circulating in the second portion 50 of the duct 40 for its part being able to be sprayed into the receptacle 14 at the second spraying orifice 42b.

Advantageously, the number of spraying orifices 42 is at least equal to the number of portions with different cross-sections which the duct 40 comprises, with at least one dielectric fluid spraying orifice 42 positioned on each portion of the duct 40. In the example illustrated here in FIG. 3, the distribution system 26 comprises a duct with eight portions and sixteen spraying orifices 42, and each portion of the duct 40 comprises at least two spraying orifices 42.

As previously stated, the two spraying orifices 42 of each of the portions of the duct 40 are positioned opposite one another relative to the main direction extension A of the duct 40. In addition, each spraying orifice 42 of each of the portions of the duct 40 is facing one of the electrical and/or electronic components 6.

The duct 40 can be formed by a plurality of coaxial tubular elements 54 with different transverse cross-sections and different lengths, or a plurality of flat elements stacked on one another in a vertical direction V, with different lengths. In other words, the duct 40 comprises a plurality of tubular elements 54 which are imbricated with one another, such that at least one tubular element 54 is positioned around another tubular element 54, with a space between the two tubular elements in order to leave a passage for the dielectric fluid coming from the dielectric fluid output of the heat exchanger. “Coaxial” means that each tubular element 54 which constitutes the duct 40 has a form of revolution around an axis of revolution, in this case parallel to the main direction of extension A of the duct 40, and all the axes of revolution are combined. The dielectric fluid can circulate in each of the tubular elements 54 of the duct 40. More particularly, the dielectric fluid circulates in the duct 40, between the inner face of a first tubular element 54, and the outer face of another tubular element 54 surrounded by the first tubular element 54, from the dielectric fluid output 36 of the heat exchanger 24, as far as a spraying orifice 42 positioned on a free portion 56 of the first tubular element 54, i.e. a portion which is not covered by the adjacent tubular element which surrounds it.

Each portion of the duct 40 is formed by a free portion 56 of one of the tubular elements 54 which is not covered by another tubular element 54. In other words, a first part of the tubular element 54 is covered by an adjacent tubular element, and a second part of this tubular element 54 is unobstructed facing the receptacle 14, and the free portion 56 of the tubular elements 54 represents this second part of said tubular elements 54.

In order to provide a duct, the cross-section of passage of which decreases going away from the heat exchanger 24, and to permit the formation for each tubular element of a free portion via which the dielectric fluid can be sprayed towards the electrical and/or electronic components, the tubular element which is positioned most centrally, and is therefore surrounded at least partly by each of the other tubular elements, has a longitudinal dimension larger than that of the others, and the longitudinal dimension of the other tubular elements decreases going away from the center of the duct, i.e. from the common axis of revolution of the tubular elements. Each tubular element 54 thus has a first longitudinal end in the vicinity of the dielectric fluid output 36 of the heat exchanger 24, and a second longitudinal end opposite, which extends at a distance specific to this tubular element, and each tubular element has a different length, each length being measured in a direction parallel to the main direction of extension A of the duct. The free end of each tubular element is closed, and only the adjacent tubular element closest to the center of the duct passes through it, such that the dielectric fluid which circulates between these two tubular elements can not go beyond this free end, and is forced to exit via the spraying orifices positioned on the free portion of the corresponding tubular element.

As illustrated in FIG. 3, at least one spraying orifice 42 is positioned at the free portion 56 of each of the tubular elements 54, i.e. at each portion of the duct 40, in order to permit regular exiting of the dielectric fluid in the direction of the receptacle.

Advantageously, each free portion 56 comprises two spraying orifices 42 opposite one another, if applicable diametrically opposite, with reference to a direction perpendicular to the main direction of extension A of the duct 40.

The number of portions of the duct is equal to the number of electrical and/or electronic components 6 in a row of these components, and each of the spraying orifices 42 is positioned facing one of the electrical and/or electronic components 6.

A second embodiment of the invention, shown in FIG. 4, differs from the first embodiment in that the cross-section of passage of the duct 40 in this case decreases continuously going away from the dielectric fluid output 36 of the heat exchanger 40, and no longer in steps.

In other words, the distribution system 26 is configured in this second example such as to define a duct 40 with a frusto-conical form, with a tip of the cone which is axially opposite the dielectric fluid output 36 of the heat exchanger 24.

The spraying orifices 42 are distributed on the wall delimiting the frusto-conical form of the duct, such as to be facing an electrical and/or electronic component. In the example illustrated, these orifices are regularly distributed from the dielectric fluid output 36 of the heat exchanger 24.

As it has just been described, and in particular via the two embodiments illustrated, the present invention fulfils the objective which it had set out of homogeneous distribution of dielectric fluid in a housing accommodating electrical and electronic components, for the purpose of homogeneous cooling of each of these components. Whether the duct has a frusto-conical form, or a form with successive steps, the specific form of the duct according to the invention makes it possible, going away from the heat exchanger, to reduce the cross-section of passage of the dielectric fluid, and thus give rise to load losses, in this case continuously, making it possible to force the dielectric fluid to be distributed homogeneously along the entire dimension of extension of the duct.

However, the present invention is not limited to the means and configurations described and illustrated here, and also extends to any equivalent means and configurations, as well as to any technically operative combination of such means, provided that a dielectric fluid is made to circulate in a duct with a developing cross-section provided with spraying orifices arranged facing a row of electrical and/or electronic components.

1. A temperature-regulating device for a plurality of electrical and/or electronic components which can release heat when in operation,
the temperature-regulating device comprising a housing which is configured to accommodate the electrical and/or electronic components, and
the temperature-regulating device further comprises temperature-regulating means for regulating the temperature of the electrical or electronic components with a dielectric fluid which is able to immerse the electrical or electronic components at least partly,
wherein the temperature-regulating means comprise firstly a heat exchanger through which the dielectric fluid can pass, and a heat-transfer fluid,
wherein the heat exchanger comprises at least one dielectric fluid input and one dielectric fluid output,
wherein the temperature-regulating means further comprises:
a system for distribution of the dielectric fluid which is positioned at the dielectric fluid output of the heat exchanger, and
at least two dielectric fluid spraying orifices,
wherein the distribution system participates in delimiting at least partly a duct which extends in a main direction of extension in the prolongation of the dielectric fluid output of the heat exchanger,
wherein the duct is configured such as to have a variable cross-section of passage for the dielectric fluid.

2. The temperature-regulating device as claimed in claim 1,
wherein the orifices for spraying of the dielectric fluid are distributed along the duct, in the main direction of extension of the duct.

3. The temperature-regulating device as claimed in claim 1,
wherein the spraying orifices are distributed in pairs,
wherein the orifices for spraying of the dielectric fluid of each pair are positioned opposite one another relative to a direction perpendicular to the main direction of extension of the duct.

4. The temperature-regulating device as claimed in claim 1,
wherein the cross-section of passage of the duct decreases going away from the dielectric fluid output of the heat exchanger.

5. The temperature-regulating device as claimed in claim 4,
wherein the cross-section of passage of the duct decreases continuously going away from the dielectric fluid output of the heat exchanger.

6. The temperature-regulating device as claimed in claim 4,
wherein the cross-section of passage of the duct decreases in successive steps going away from the dielectric fluid output of the heat exchanger, forming a plurality of successive portions with different cross-sections of passage.

7. The temperature-regulating device as claimed in claim 6,
wherein the distribution system comprises at least one first dielectric fluid spraying orifice which is positioned on a portion of the duct,
wherein the distribution system further comprises at least one second dielectric fluid spraying orifice which is positioned on another portion.

8. The temperature-regulating device as claimed in claim 7,
wherein the distribution system comprises a plurality of dielectric fluid spraying orifices,
wherein the number of spraying orifices is at least equal to the number of portions with different cross-sections which the duct comprises.

9. The temperature-regulating device as claimed in claim 6,
wherein the duct is formed by a plurality of coaxial tubular elements with different transverse cross-sections and different lengths.

10. An electronic system comprising electrical and/or electronic components and a temperature-regulating device as claimed in claim 1,
wherein the electrical and/or electronic components are distributed in at least two rows,
wherein the rows extend parallel to a main direction of extension of the duct,
wherein the distribution system extends at least partly between two rows of electrical and/or electronic components.
